(19) United States
(12) Patent Application Publication
(10) Pub. No.: US 2022/0093777 A1
(43) Pub. Date: Mar. 24, 2022

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Takeshi SUWA, Kawasaki Kanagawa (JP); Tomoko MATSUDAI, Shibuya Tokyo (JP); Yoko IWAKAJI, Meguro Tokyo (JP); Hiroko ITOKAZU, Kawasaki Kanagawa (JP)

(21) Appl. No.: 17/175,233

(22) Filed: Feb. 12, 2021

(30) Foreign Application Priority Data
Sep. 18, 2020 (JP) 2020-157707

(51) Int. Cl. H01L 29/739; H01L 29/06

(52) U.S. Cl. CPC H01L 29/7397; H01L 29/0615

(57) ABSTRACT

A semiconductor device includes first and second electrodes, first to fifth layers of semiconductor, first and second control electrodes. The first and third layers are of a first conductivity type. The second, fourth and fifth layers are of a second conductivity type. The first layer is provided between the first and second electrodes. The second and third layers are provided between the first layer and the second electrode. The fourth layer is provided between the first layer and the first electrode. The first and second control electrodes are provided respectively inside trenches and arranged along a boundary between the first and second layers. The fifth layer is provided between the first and second control electrodes, and includes first and second portions. The first portion is provided in the first layer. The second portion is provided between the first and second layers and electrically connected to the first portion.

### CROSS-REFERENCE TO RELATED APPLICATIONS

This application is based upon and claims the benefit of priority from Japanese Patent Application No. 2020-157707, filed on Sep. 18, 2020; the entire contents of which are incorporated herein by reference.

### FIELD

Embodiments relate to a semiconductor device.

### BACKGROUND

A semiconductor device is used in a power converter such as an inverter or the like. For example, it is desirable for such a device to have large breakdown immunity to an electric current locally concentrated in a turn-off period.

### BRIEF DESCRIPTION OF THE DRAWINGS

FIG. 1 is a schematic cross-sectional view showing a semiconductor device according to a first embodiment;

FIGS. 2A and 2B are schematic cross-sectional views illustrating operations of the semiconductor device according to the first embodiment;

FIGS. 3A and 3B are graphs showing characteristics of the semiconductor device according to the first embodiment;

FIG. 4 is a graph showing another characteristic of the semiconductor device according to the first embodiment;

FIGS. 5A to 5C are schematic views showing a semiconductor device according to a first modification of the first embodiment;

FIGS. 6A to 6C are schematic views showing a semiconductor device according to a second modification of the first embodiment;

FIGS. 7A and 7B are schematic views showing a semiconductor device according to a third modification of the first embodiment;

FIGS. 8A to 8C are schematic views illustrating the fifth semiconductor layer according to modifications of the first embodiment;

FIGS. 9A and 9B are schematic views showing a semiconductor device according to a fourth modification of the first embodiment;

FIGS. 10A and 10B are schematic views showing semiconductor devices according to a fifth modification of the first embodiment;

FIGS. 11A and 11B are schematic views showing semiconductor devices according to a sixth modification of the first embodiment; and

FIG. 12 is a schematic cross-sectional view showing a semiconductor device according to a second embodiment.

### DETAILED DESCRIPTION

According to one embodiment, a semiconductor device includes first and second electrodes, first to fifth semiconductor layers, a plurality of control electrodes and a first insulating film. The second electrode faces the first electrode. The first semiconductor layer of a first conductivity type is provided between the first electrode and the second electrode. The second semiconductor layer of a second conductivity type is provided between the first semiconductor layer and the second electrode. The second semiconductor layer is electrically connected to the second electrode. The third semiconductor layer of the first conductivity type is provided between the second semiconductor layer and the second electrode. The third semiconductor layer is electrically connected to the second electrode. The fourth semiconductor layer of the second conductivity type is provided between the first semiconductor layer and the first electrode. The fourth semiconductor layer is electrically connected to the first electrode. The control electrodes are provided respectively inside trenches extending into the first semiconductor layer from the third semiconductor layer. Each of the control electrodes extends in a first direction from the second electrode toward the first electrode. The control electrodes are arranged in a second direction along a boundary between the first semiconductor layer and the second semiconductor layer. The control electrodes include first and second control electrodes that are mutually-adjacent. The first insulating film is provided between the first semiconductor layer and each of the control electrodes and between the second semiconductor layer and each of the control electrodes. The fifth semiconductor layer of the second conductivity type is provided between the first and second control electrodes. The fifth semiconductor layer includes first and second portions. The first portion of the fifth semiconductor layer is provided in the first semiconductor layer and is provided between the third semiconductor layer and the fourth semiconductor layer. The second portion of the fifth semiconductor layer is provided between the first semiconductor layer and the second semiconductor layer and is electrically connected to the first portion of the fifth semiconductor layer and the second semiconductor layer.

Embodiments will now be described with reference to the drawings. The same portions inside the drawings are marked with the same numerals; a detailed description is omitted as appropriate; and the different portions are described. The drawings are schematic and conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

### First Embodiment

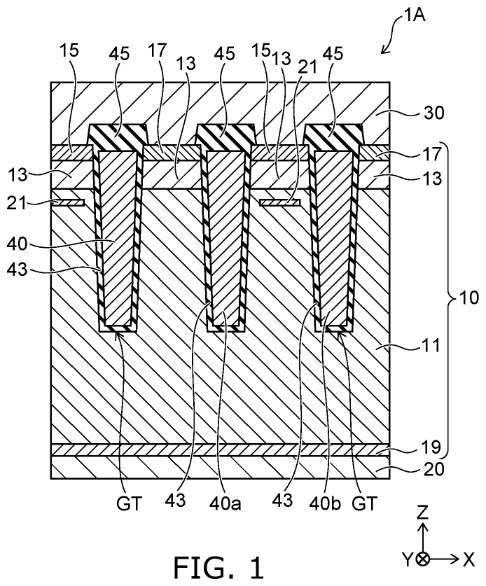

FIG. 1 is a schematic cross-sectional view showing a semiconductor device 1A according to a first embodiment. The semiconductor device 1A is, for example, an IGBT (Insulated Gate Bipolar Transistor).

As illustrated in FIG. 1, the semiconductor device 1A includes a semiconductor part 10, a first electrode 20, a second electrode 30, and a control electrode 40. The first electrode 20 is, for example, a collector electrode. The second electrode 30 is, for example, an emitter electrode. The control electrode 40 is, for example, a gate electrode.

The first electrode 20 and the second electrode 30 are provided at positions facing each other; and the semiconductor part 10 is provided between the first electrode 20 and the second electrode 30. For example, the first electrode 20 is provided on the back surface of the semiconductor part 10. The second electrode 30 is provided at the front side of the semiconductor part 10. The semiconductor part 10 is, for example, silicon. The first electrode 20 and the second electrode 30 are, for example, metal layers including aluminum.

The semiconductor part 10 includes, for example, a first semiconductor layer 11 of a first conductivity type, a second semiconductor layer 13 of a second conductivity type, a third semiconductor layer 15 of the first conductivity type, a fourth semiconductor layer 19 of the second conductivity type, and a fifth semiconductor layer 21 of the second conductivity type. In the description hereinbelow, the first conductivity type is taken to be an n-type, and the second conductivity type is taken to be a p-type.

The first semiconductor layer 11 is, for example, an n-type base layer. The first semiconductor layer 11 extends between the first electrode 20 and the second electrode 30.

The second semiconductor layer 13 is, for example, a p-type base layer. The second semiconductor layer 13 is provided between the first semiconductor layer 11 and the second electrode 30. For example, the second semiconductor layer 13 is electrically connected to the second electrode 30 via a sixth semiconductor layer 17 of the second conductivity type. The sixth semiconductor layer 17 is, for example, a p-type emitter layer. The sixth semiconductor layer 17 includes a second-conductivity-type impurity with a higher concentration than a concentration of the second-conductivity-type impurity in the second semiconductor layer 13.

The third semiconductor layer 15 is, for example, an n-type emitter layer. The third semiconductor layer 15 is selectively provided between the second semiconductor layer 13 and the second electrode 30. The third semiconductor layer 15 is electrically connected to the second electrode 30.

The fourth semiconductor layer 19 is, for example, a p-type collector layer. The fourth semiconductor layer 19 is provided between the first semiconductor layer 11 and the first electrode 20. The fourth semiconductor layer 19 is electrically connected to the first electrode 20.

The semiconductor part 10 has a trench GT provided at the front side thereof, and the control electrode 40 is provided inside the trench GT. The trench GT has a depth from the front surface (the upper surface) of the third semiconductor layer 15 into the first semiconductor layer 11.

The control electrode 40 is, for example, conductive polysilicon. The control electrode 40 is electrically insulated from the first semiconductor layer 11, the second semiconductor layer 13, the third semiconductor layer 15, and the sixth semiconductor layer 17 by a first insulating film 43. The first insulating film 43 is, for example, a gate insulating film. The first insulating film 43 is, for example, a silicon oxide film.

The control electrode 40 is provided between the semiconductor part 10 and the second electrode 30. The control electrode 40 is electrically insulated from the second electrode 30 by a second insulating film 45. The second insulating film 45 is, for example, an inter-layer insulating film. The second insulating film 45 is, for example, a silicon oxide film.

The control electrode 40 includes a portion that is positioned in the first semiconductor layer 11 and faces the first semiconductor layer 11 via the first insulating film 43. The control electrode 40 also faces the second semiconductor layer 13 via the first insulating film 43. In other words, the first insulating film 43 is provided between the first semiconductor layer 11 and the control electrode 40 and between the second semiconductor layer 13 and the control electrode 40. The third semiconductor layer 15 contacts the first insulating film 43.

For example, multiple control electrodes 40 are arranged in a direction (e.g., the X-direction) along the boundary between the first semiconductor layer 11 and the second semiconductor layer 13. The multiple control electrodes 40 include a first control electrode 40a and a second control electrode 40b.

For example, the third semiconductor layer 15 is provided between the first control electrode 40a and the second control electrode 40b. The fifth semiconductor layer 21 also is provided between the first control electrode 40a and the second control electrode 40b.

The fifth semiconductor layer 21 is provided in the first semiconductor layer 11. For example, the fifth semiconductor layer 21 includes a second-conductivity-type impurity with a higher concentration than a concentration of the second-conductivity-type impurity in the second semiconductor layer 13. The first semiconductor layer 11 includes a portion provided between the second semiconductor layer 13 and the fifth semiconductor layer 21 and a portion provided between the fifth semiconductor layer 21 and the first insulating film 43.

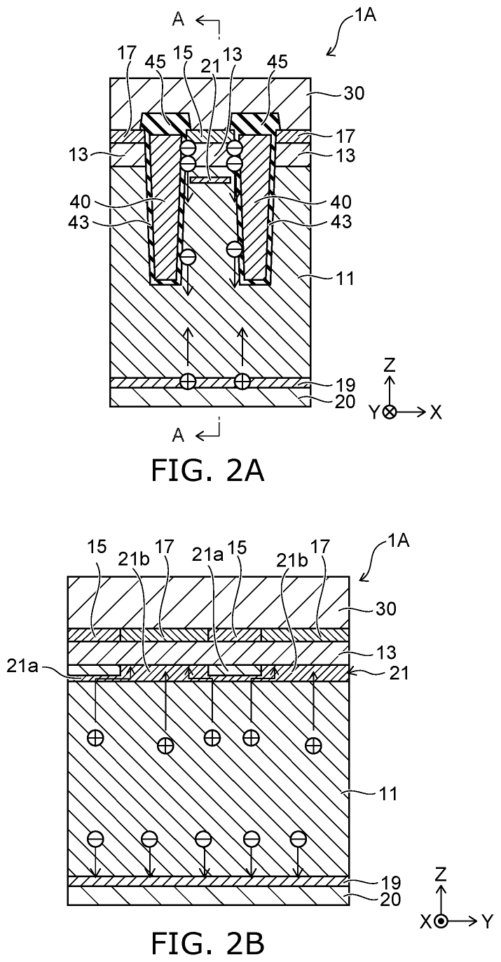

FIGS. 2A and 2B are schematic cross-sectional views illustrating operations of the semiconductor device 1A according to the first embodiment. FIG. 2A is a schematic view illustrating a portion of the cross section shown in FIG. 1. FIG. 2B is a schematic view illustrating an A-A cross section shown in FIG. 2A.

FIG. 2A shows the flow of electrons and holes in the on-state of the semiconductor device 1A. For example, an inversion layer of the first conductivity type is induced at the interface between the second semiconductor layer 13 and the first insulating film 43 when a gate voltage that is greater than the threshold voltage of the control electrode 40 (i.e., an on-voltage) is applied between the second electrode 30 and the control electrode 40. Thereby, electrons are injected from the third semiconductor layer 15 into the first semiconductor layer 11 via the inversion layer. Accordingly, holes are injected from the fourth semiconductor layer 19 into the first semiconductor layer 11.

As shown in FIG. 2B, for example, the second semiconductor layer 13 extends in the Y-direction between the first semiconductor layer 11 and the second electrode 30. For example, the third semiconductor layer 15 and the sixth semiconductor layer 17 are alternately arranged in the extension direction of the second semiconductor layer 13.

The fifth semiconductor layer 21 includes a first portion 21a and a second portion 21b. The first portion 21a is provided below the third semiconductor layer 15. The first portion 21a is provided in the first semiconductor layer 11 and is positioned between the third semiconductor layer 15 and the fourth semiconductor layer 19. The first semiconductor layer 11 includes a portion provided between the second semiconductor layer and the first portion 21a.

On the other hand, the second portion 21b is provided below the sixth semiconductor layer 17. The second portion 21b is provided between the first semiconductor layer 11 and the sixth semiconductor layer 17. The second portion 21b is provided between the first semiconductor layer 11 and the second semiconductor layer 13. The second portion 21b is electrically connected to the second semiconductor layer 13.

The first portion 21a is linked to the second portion 21b. In other words, the first portion 21a is electrically connected to the second semiconductor layer 13 via the second portion 21b.

FIG. 2B illustrates the flow of electrons and holes in the turn-off period of the semiconductor device 1A. For example, when the gate voltage that is applied between the second electrode 30 and the control electrode 40 is reduced to an off-voltage that is less than the threshold voltage of the control electrode 40, the inversion layer that was induced at the interface between the second semiconductor layer 13 and the first insulating film 43 disappears.

The turn-off process of the semiconductor device 1A starts when the electron injection from the third semiconductor layer 15 into the first semiconductor layer 11 via the inversion layer is stopped. When the electron injection into the first semiconductor layer 11 is stopped, the hole injection from the fourth semiconductor layer 19 into the first semiconductor layer 11 also is stopped. Therefore, the voltage between the first electrode 20 and the second electrode 30 increases, and the first semiconductor layer 11 is depleted. The electrons in the first semiconductor layer 11 are ejected into the first electrode 20 via the fourth semiconductor layer 19. The holes in the first semiconductor layer 11 are ejected into the second electrode 30 via the second semiconductor layer 13 and the sixth semiconductor layer 17.

In the semiconductor device 1A, the ejection of the holes into the second electrode 30 is promoted by the fifth semiconductor layer 21 provided between the first semiconductor layer 11 and the second semiconductor layer 13.

As shown in FIG. 2B, the electrons in the first semiconductor layer 11 are ejected into the first electrode 20 via the fourth semiconductor layer 19. On the other hand, the holes in the first semiconductor layer 11 are ejected into the second electrode 30 via the second portion 21b of the fifth semiconductor layer 21, the second semiconductor layer 13 and the sixth semiconductor layer 17. The holes in the first semiconductor layer 11 move from the first portion 21a of the fifth semiconductor layer 21 toward the second portion 21b and are ejected via the path of the second and sixth semiconductor layers 13 and 17. Thereby, the electrons and holes in the first semiconductor layer 11 can be efficiently ejected into the first and second electrodes 20 and 30; and the first semiconductor layer 11 can be depleted.

Further, it is possible to suppress the hole injection into the portion of the second semiconductor layer 13 provided between the first semiconductor layer 11 and the third semiconductor layer 15 by the first portion 21a of the fifth semiconductor layer 21 that blocks the hole ejection path toward the third semiconductor layer 13 and makes holes detour to the sixth semiconductor layer 17. The impurity concentration in the first portion 21a may be higher than that in the first semiconductor layer 11. Thereby, it is possible to prevent the turn-on effect of a parasitic n-p-n transistor formed of the first semiconductor layer 11, the second semiconductor layer 13, and the third semiconductor layer 15.

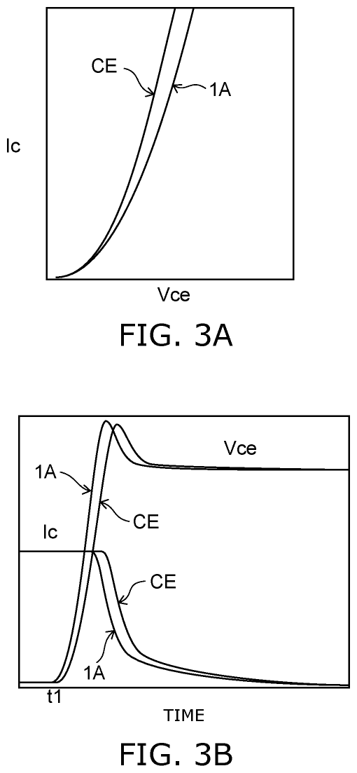

FIGS. 3A and 3B are graphs showing characteristics of the semiconductor device 1A according to the first embodiment. FIG. 3A illustrates the relationship of a voltage Vce and a current Ic between the first electrode 20 and the second electrode 30 in the on-state. FIG. 3B illustrates the temporal change of the current Ic and the voltage Vce between the first electrode 20 and the second electrode 30 in the turn-off process. The figures show characteristics of the semiconductor device 1A and a semiconductor device CE according to a comparative example. The semiconductor device CE differs from the semiconductor device 1A in that the fifth semiconductor layer 21 is not included.

As shown in FIG. 3A, the on-current of the semiconductor device 1A is less than the on-current of the semiconductor device CE. This reflects a larger on-resistance due to the reduction of the electron current path by providing the first portion 21a of the fifth semiconductor layer 21 (referring to FIG. 2A).

On the other hand, as shown in FIG. 3B, the gate voltage is set to be not more than the threshold voltage of the control electrode 40 at a time t1, and then the voltage Vce of the semiconductor device 1A rises faster than the voltage Vce of the semiconductor device CE. Also, the current Ic of the semiconductor device 1A decreases faster than the current Ic of the semiconductor device CE. Thus, the turn-off time can be reduced by providing the fifth semiconductor layer 21, and the switching loss can be reduced in the semiconductor device 1A.

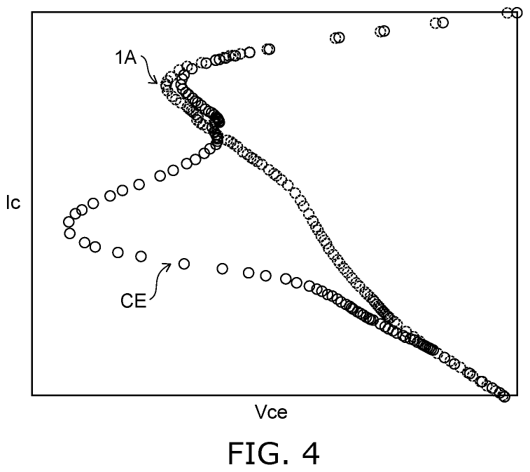

FIG. 4 is a graph showing another characteristic of the semiconductor device according to the first embodiment. This figure shows characteristics of the semiconductor device 1A and the semiconductor device CE according to the comparative example.

For example, when the parasitic n-p-n transistor turns on during the turn-off process of the semiconductor device, a so-called snapback phenomenon occurs in which the voltage Vce decreases as the current Ic increases. As shown in FIG. 4, the voltage Vce decreases as the current Ic increases, and then the voltage Vce starts to increase. When the decrease amount of the voltage Vce is large in this process, the current concentration easily occurs due to the turned-on of the parasitic n-p-n transistor, and the breakdown immunity of the semiconductor device decreases.

In the example shown in FIG. 4, the decrease of the voltage Vce of the semiconductor device 1A is suppressed compared to the semiconductor device CE. This shows that the current is reduced which flows due to the turn-on of the parasitic n-p-n transistor. In other words, the fifth semiconductor layer 21 increases the breakdown immunity in the turn-off period of the semiconductor device 1A.

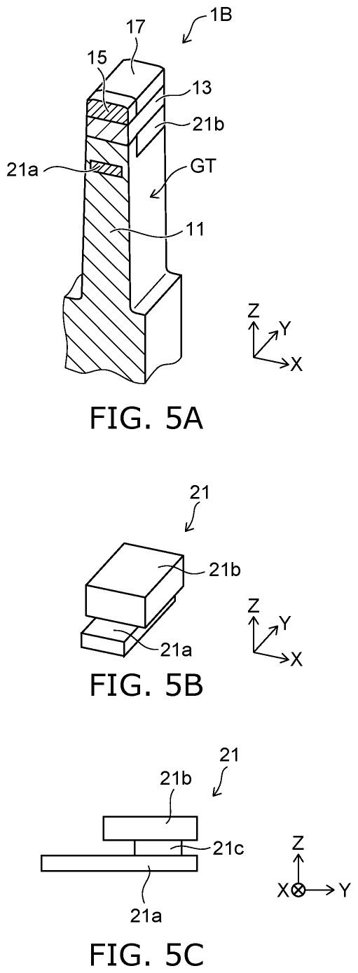

FIGS. 5A to 5C are schematic views showing a semiconductor device 1B according to a first modification of the first embodiment.

FIG. 5A is a perspective view showing the first semiconductor layer 11, the second semiconductor layer 13, the third semiconductor layer 15, and the sixth semiconductor layer 17 which are provided between the mutually-adjacent first and second control electrodes 40a and 40b (referring to FIG. 1).

FIG. 5B is a perspective view showing the fifth semiconductor layer 21; and FIG. 5C is a cross-sectional view of the fifth semiconductor layer 21 along the Y-Z plane.

As shown in FIGS. 5A to 5C, the fifth semiconductor layer 21 includes the first portion 21a, the second portion 21b, and a third portion 21c. The third portion 21c links the first portion 21a and the second portion 21b.

The first portion 21a is electrically connected to the second portion 21b via the third portion 21c. The first portion 21a is provided to extend into the region of the first semiconductor layer 11 below the sixth semiconductor layer 17 from the position below the third semiconductor layer 15.

As shown in FIG. 5A, the second portion 21b faces the control electrode 40 via the first insulating film 43 (not-illustrated). In other words, the ejection resistance of the holes from the first semiconductor layer 11 into the second electrode 30 is reduced by increasing the width in the X-direction of the second portion 21b. On the other hand, the path of the electron current flowing from the third semiconductor layer 15 toward the first semiconductor layer 11 is limited to regions in which the second portion 21b is not provided.

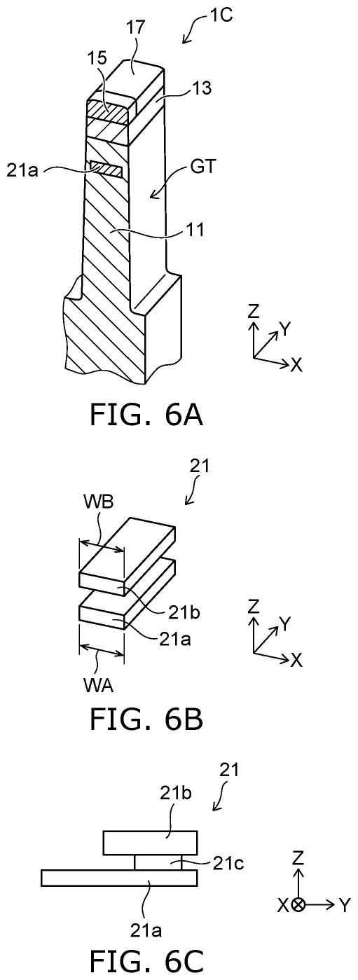

FIGS. 6A to 6C are schematic views showing a semiconductor device 1C according to a second modification of the first embodiment.

FIG. 6A is a perspective view showing the first semiconductor layer 11, the second semiconductor layer 13, the third semiconductor layer 15, and the sixth semiconductor layer 17 which are provided between the mutually-adjacent first and second control electrodes 40a and 40b (referring to FIG. 1).

FIG. 6B is a perspective view showing the fifth semiconductor layer 21; and FIG. 6C is a cross-sectional view of the fifth semiconductor layer 21 along the Y-Z plane.

As shown in FIGS. 6A to 6C, the fifth semiconductor layer 21 includes the first portion 21a, the second portion 21b, and the third portion 21c. The third portion 21c links the first portion 21a and the second portion 21b.

The first portion 21a is electrically connected to the second portion 21b via the third portion 21c. The first portion 21a is provided to extend into the region of the first semiconductor layer 11 below the sixth semiconductor layer 17 from the position below the third semiconductor layer 15. In the example, a width WB in the X-direction of the second portion 21b is substantially equal to a width WA in the X-direction of the first portion 21a.

The first semiconductor layer 11 includes a portion positioned between the first insulating film 43 (not illustrated) and the second portion 21b of the fifth semiconductor layer 21. Thereby, the path of the electron current flowing from the third semiconductor layer 15 toward the first semiconductor layer 11 also spreads to regions positioned between the first semiconductor layer 11 and the sixth semiconductor layer 17. In other words, the on-resistance of the semiconductor device 1C can be reduced.

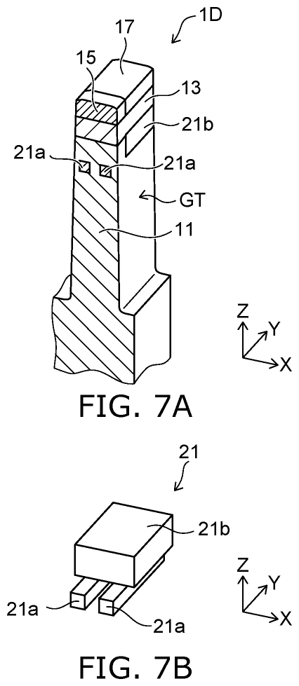

FIGS. 7A and 7B are schematic views showing a semiconductor device 1D according to a third modification of the first embodiment.

FIG. 7A is a perspective view showing the first semiconductor layer 11, the second semiconductor layer 13, the third semiconductor layer 15, and the sixth semiconductor layer 17 which are provided between the mutually-adjacent first and second control electrodes 40a and 40b (referring to FIG. 1). FIG. 7B is a perspective view showing the fifth semiconductor layer 21.

In the example, the fifth semiconductor layer 21 includes two first portions 21a and the second portion 21b. For example, the two first portions 21a are arranged in the X-direction. The first semiconductor layer 11 includes a portion provided between the two first portions 21a, and a portion provided between the first insulating film 43 (not-illustrated) and the first portions 21a. The path of the electron current flowing from the third semiconductor layer 15 toward the first semiconductor layer 11 via the inversion layer can be widened thereby.

As shown in FIG. 7A, the second portion 21b faces the control electrode 40 via the first insulating film 43 (not-illustrated). In other words, by increasing the width in the X-direction of the second portion 21b, the ejection resistance of the holes from the first semiconductor layer 11 toward the second electrode 30 is reduced.

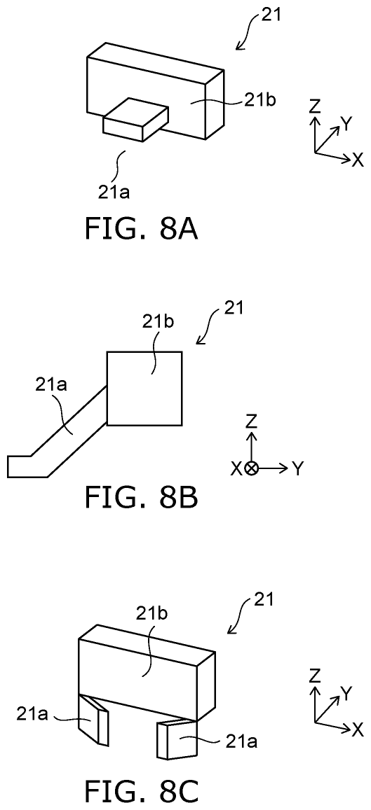

FIGS. 8A to 8C are schematic views illustrating the fifth semiconductor layer 21 according to modifications of the first embodiment. FIGS. 8A and 8C are perspective views; FIG. 8B is a Y-Z cross-sectional view. In these examples, the fifth semiconductor layer 21 also includes the first portion 21a and the second portion 21b; and the first portion 21a is electrically connected to the second portion 21b.

In the example shown in FIG. 8A, the first portion 21a protrudes in the −Y direction (the reverse direction of the Y-direction) from the side surface of the second portion 21b.

In the example shown in FIG. 8B, the first portion 21a protrudes obliquely downward from the side surface of the second portion 21b. The first portion 21a is provided at a position apart from the second semiconductor layer 13 in the Z-direction. Thereby, the holes can be efficiently ejected from the first semiconductor layer 11 via the first portion 21a.

The two first portions 21a are provided in the example shown in FIG. 8C. For example, the two first portions 21a are arranged in the X-direction; and the spacing between the two first portions 21a becomes narrower away from the second portion 21b. The path of the electron current flowing from the third semiconductor layer 15 toward the first semiconductor layer 11 via the inversion layer can be widened thereby, and the holes can be efficiently ejected from the first semiconductor layer 11.

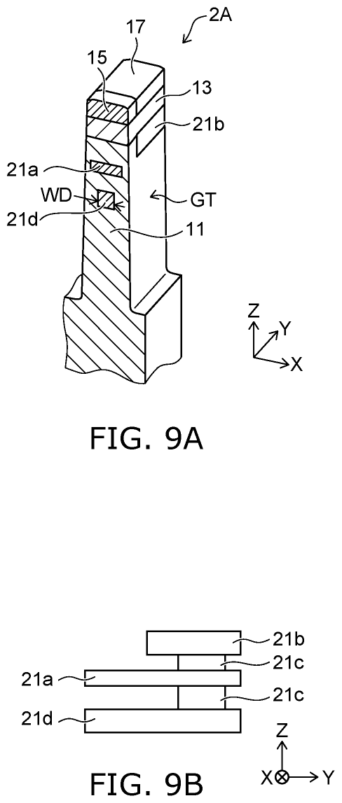

FIGS. 9A and 9B are schematic views showing a semiconductor device 2A according to a fourth modification of the first embodiment.

FIG. 9A is a perspective view showing the first semiconductor layer 11, the second semiconductor layer 13, the third semiconductor layer 15, and the sixth semiconductor layer 17 which are provided between the mutually-adjacent first and second control electrodes 40a and 40b (referring to FIG. 1). FIG. 9B is a cross-sectional view of the fifth semiconductor layer 21 along the Y-Z plane.

As shown in FIG. 9A, the fifth semiconductor layer 21 further includes a fourth portion 21d. The fourth portion 21d is provided below the first portion 21a. A width WD in the X-direction of the fourth portion 21d is less than the width WA in the X-direction of the first portion 21a (referring to FIG. 6B). The second portion 21b faces the control electrode 40 via the first insulating film 43 (not-illustrated).

As shown in FIG. 9B, the first portion 21a is provided between the second portion 21b and the fourth portion 21d. The fourth portion 21d is electrically connected to the first portion 21a via the third portion 21c. The first portion 21a is electrically connected to the second portion 21b via another third portion 21c.

The fourth portion 21d is provided to extend into the region of the first semiconductor layer 11 below the sixth semiconductor layer 17 from the position below the third semiconductor layer 15. In the example, the holes of the first semiconductor layer 11 can be more efficiently ejected through the fourth portion 21d.

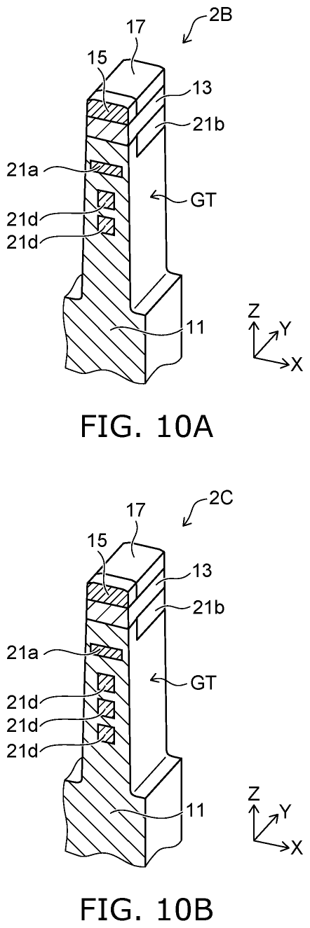

FIGS. 10A and 10B are schematic views showing semiconductor devices 2B and 2C according to a fifth modification of the first embodiment. FIGS. 10A and 10B are perspective views showing the first semiconductor layer 11, the second semiconductor layer 13, the third semiconductor layer 15, and the sixth semiconductor layer 17 which are provided between the mutually-adjacent first and second control electrodes 40a and 40b (referring to FIG. 1).

In the semiconductor device 2B shown in FIG. 10A, the fifth semiconductor layer 21 includes two fourth portions 21d arranged in the Z-direction. The two fourth portions 21d are electrically connected to each other via the third portion 21c (not-illustrated) and are electrically connected to the first portion 21a (referring to FIG. 9B).

In the semiconductor device 2C shown in FIG. 10B, the fifth semiconductor layer 21 includes three fourth portions 21d arranged in the Z-direction. The three fourth portions 21d are electrically connected to each other via the third portion 21c (not-illustrated) and are electrically connected to the first portion 21a (referring to FIG. 9B).

Thus, by arranging the multiple fourth portions 21d in the Z-direction, the holes of the first semiconductor layer 11 can be more efficiently ejected.

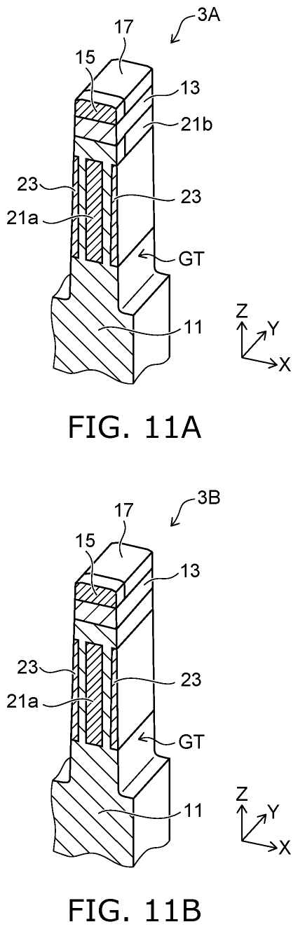

FIGS. 11A and 11B are schematic views showing semiconductor devices 3A and 3B according to a sixth modification of the first embodiment. FIGS. 11A and 11B are perspective views showing the first semiconductor layer 11, the second semiconductor layer 13, the third semiconductor layer 15, and the sixth semiconductor layer 17 which are provided between the mutually-adjacent first and second control electrodes 40a and 40b (referring to FIG. 1).

In the semiconductor device 3A shown in FIG. 11A, the first portion 21a of the fifth semiconductor layer 21 extends in the Z-direction below the third semiconductor layer 15. Also, the first portion 21a extends in the Y-direction and is electrically connected to the second portion 21b below the sixth semiconductor layer 17. The second portion 21b faces the control electrode 40 via the first insulating film 43 (not-illustrated).

In the example, a seventh semiconductor layer 23 of the first conductivity type is further provided between the first portion 21a and the first insulating film 43. The seventh semiconductor layer 23 extends, for example, in the Y-direction and the Z-direction along the first insulating film 43 (not-illustrated). The seventh semiconductor layer 23 includes a first-conductivity-type impurity with a higher concentration than a concentration of the first-conductivity-type impurity in the first semiconductor layer 11.

The first semiconductor layer 11 includes a portion positioned between the seventh semiconductor layer 23 and the first portion 21a of the fifth semiconductor layer 21.

In the example, because the first portion 21a of the fifth semiconductor layer 21 extends in the Z-direction, the holes in the first semiconductor layer 11 can be ejected efficiently. By providing the seventh semiconductor layer 23, the electrical resistance can be reduced in the path of the electron current reaching the first semiconductor layer 11 from the third semiconductor layer 15 via the inversion layer. The on-resistance of the semiconductor device 3A can be reduced thereby.

The semiconductor device 3B shown in FIG. 11B also includes the seventh semiconductor layer 23 and the first portion 21a of the fifth semiconductor layer 21 extending in the Z-direction. For example, the width WB in the X-direction of the second portion 21b (not illustrated) of the fifth semiconductor layer 21 is substantially equal to the width WA in the X-direction of the first portion 21a (referring to FIG. 6B). Therefore, the first semiconductor layer 11 further includes a portion positioned between the second portion 21b (not illustrated) and the first insulating film 43. Therefore, the on-resistance of the semiconductor device 3B can be further reduced.

### Second Embodiment

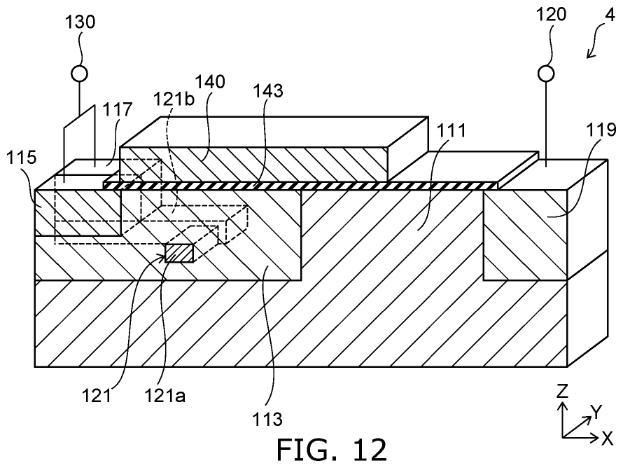

FIG. 12 is a schematic cross-sectional view showing a semiconductor device 4 according to a second embodiment. The semiconductor device 4 includes, for example, a first semiconductor layer 111 of the first conductivity type, a second semiconductor layer 113 of the second conductivity type, a third semiconductor layer 115 of the first conductivity type, a fourth semiconductor layer 119 of the second conductivity type, a fifth semiconductor layer 121 of the second conductivity type, and a sixth semiconductor layer 117 of the second conductivity type. The semiconductor device 4 also includes a first electrode 120, a second electrode 130, a control electrode 140, and a first insulating film 143.

As shown in FIG. 12, the control electrode 140 is, for example, a gate electrode and is provided selectively on the first semiconductor layer 111. The first semiconductor layer 111 is, for example, an n-type base layer. The first insulating film 143 is provided between the first semiconductor layer 111 and the control electrode 140. The first insulating film 143 is, for example, a gate insulating film. In other words, the semiconductor device 4 is an IGBT that has a planar gate structure.

The second semiconductor layer 113 is, for example, a p-type base layer. The second semiconductor layer 113 is provided selectively on the first semiconductor layer 111. The second semiconductor layer 113 includes a portion provided between the first semiconductor layer 111 and the first insulating film 143. In other words, the second semiconductor layer 113 includes a portion facing the control electrode 140 via the first insulating film 143.

The third semiconductor layer 115 is, for example, an n-type emitter layer. The third semiconductor layer 115 is provided selectively on the second semiconductor layer 113. The third semiconductor layer 115 and the portion of the second semiconductor layer 113 facing the control electrode 140 are arranged in the X-direction along the first insulating film 143.

The fourth semiconductor layer 119 is, for example, a p-type collector layer. The fourth semiconductor layer 119 is provided selectively on the first semiconductor layer 111. The fourth semiconductor layer 119 is provided at a position apart from the second semiconductor layer 113.

The fifth semiconductor layer 121 is provided in the second semiconductor layer 113. The fifth semiconductor layer 121 is provided between the first semiconductor layer 111 and the third semiconductor layer 115. The fifth semiconductor layer 121 includes a second-conductivity-type impurity with a higher concentration than the second-conductivity-type impurity of the second semiconductor layer 113.

The sixth semiconductor layer 117 is, for example, a p-type emitter layer. The sixth semiconductor layer 117 is provided selectively on the second semiconductor layer 113. The sixth semiconductor layer 117 and the third semiconductor layer 115 are arranged in the Y-direction. The sixth semiconductor layer 117 and the portion of the second semiconductor layer 113 facing the control electrode 140 are arranged in the X-direction.

The fifth semiconductor layer 121 includes a first portion 121a that is provided between the first semiconductor layer 111 and the third semiconductor layer 115, and a second portion 121b that is electrically connected to the sixth semiconductor layer 117. The first portion 121a is electrically connected to the sixth semiconductor layer 117 via the second portion 121b.

The first electrode 120 is electrically connected to the fourth semiconductor layer 119. The second electrode 130 is electrically connected to the third and sixth semiconductor layers 115 and 117.

In the turn-off process of the semiconductor device 4, the electrons in the first semiconductor layer 111 are ejected into the first electrode 120 via the fourth semiconductor layer 119. The holes in the first semiconductor layer 111 are ejected into the second electrode 130 via the second semiconductor layer 113 and the sixth semiconductor layer 117.

In the semiconductor device 4, the fifth semiconductor layer 121 is provided in the second semiconductor layer 113; therefore, the holes can be ejected efficiently from the second semiconductor layer 113 into the sixth semiconductor layer 117 through the fifth semiconductor layer 121. Thereby, the turn-on effect of the parasitic n-p-n transistor formed from the second semiconductor layer 113, the third semiconductor layer 115, and the sixth semiconductor layer 117 can be reduced, and the breakdown immunity of the semiconductor device 4 can be increased.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode facing the first electrode;
a first semiconductor layer of a first conductivity type provided between the first electrode and the second electrode;
a second semiconductor layer of a second conductivity type provided between the first semiconductor layer and the second electrode, the second semiconductor layer being electrically connected to the second electrode;
a third semiconductor layer of the first conductivity type provided between the second semiconductor layer and the second electrode, the third semiconductor layer being electrically connected to the second electrode;
a fourth semiconductor layer of the second conductivity type provided between the first semiconductor layer and the first electrode, the fourth semiconductor layer being electrically connected to the first electrode;
a plurality of control electrodes provided respectively inside trenches extending into the first semiconductor layer from the third semiconductor layer, each of the control electrodes extending in a first direction from the second electrode toward the first electrode, the control electrodes being arranged in a second direction along a boundary between the first semiconductor layer and the second semiconductor layer, the control electrodes including first and second control electrodes that are mutually-adjacent;
a first insulating film provided between the first semiconductor layer and each of the control electrodes and between the second semiconductor layer and each of the control electrodes; and
a fifth semiconductor layer of the second conductivity type provided between the first and second control electrodes, the fifth semiconductor layer including first and second portions,
the first portion of the fifth semiconductor layer being provided in the first semiconductor layer, the first portion being provided between the third semiconductor layer and the fourth semiconductor layer,
the second portion of the fifth semiconductor layer being provided between the first semiconductor layer and the second semiconductor layer, the second portion being electrically connected to the first portion of the fifth semiconductor layer and the second semiconductor layer.

2. The device according to claim 1, wherein
the first semiconductor layer includes a portion provided between the first insulating film and the first portion of the fifth semiconductor layer.

3. The device according to claim 2, wherein
the first semiconductor layer includes another portion provided between the first insulating film and the second portion of the fifth semiconductor layer.

4. The device according to claim 1, further comprising:
a sixth semiconductor layer of the second conductivity type provided between the second semiconductor layer and the second electrode, the third semiconductor layer and the sixth semiconductor layer being arranged along the second semiconductor layer,
the sixth semiconductor layer being provided between the second electrode and the second portion of the fifth semiconductor layer,
the sixth semiconductor layer including a second-conductivity-type impurity with a higher concentration than a concentration of a second-conductivity-type impurity in the second semiconductor layer,
the second semiconductor layer being electrically connected to the second electrode via the sixth semiconductor layer.

5. The device according to claim 4, wherein
the fifth semiconductor layer includes a second-conductivity-type impurity with a higher concentration than the concentration of the second-conductivity-type impurity in the second semiconductor layer.

6. The device according to claim 1, wherein
the first portion of the fifth semiconductor layer extends from the second portion in a third direction, the third direction being orthogonal to the second direction and being along the boundary between the first semiconductor layer and the second semiconductor layer.

7. The device according to claim 1, wherein
the fifth semiconductor layer further includes a third portion between the first portion and the second portion, the third portion electrically connecting the first and second portions.

8. The device according to claim 1, wherein
the fifth semiconductor layer includes a plurality of the first portions, and
the plurality of first portions is arranged in the second direction.

9. The device according to claim 1, wherein
the first portion of the fifth semiconductor layer extends in a direction crossing the first direction and a third direction, the third direction being orthogonal to the second direction and being along the boundary between the first semiconductor layer and the second semiconductor layer, and
the first portion of the fifth semiconductor layer extends toward the first electrode from the second portion in a cross section including the first and third directions.

10. The device according to claim 1, wherein
the fifth semiconductor layer includes one pair of the first portions,
the one pair of first portions is arranged in the second direction,
one of the one pair of first portions extends in a fourth direction, the fourth direction crossing the second direction and being along the boundary between the first semiconductor layer and the second semiconductor layer,
the other of the one pair of first portions extends in a fifth direction, the fifth direction crossing the second and fourth directions and being along the boundary between the first semiconductor layer and the second semiconductor layer, and
a spacing between tips of the one pair of first portions distal to the second portion is greater than a spacing between ends of the one pair of first portions connected to the second portion.

11. The device according to claim 7, wherein
the fifth semiconductor layer further includes another third portion and at least one fourth portion, the second portion and the at least one fourth portion being arranged in the first direction, said another third portion electrically connecting the first portion and the at least one fourth portion via the second portion and the third portion; and
the first portion and the second portion are provided between the at least one fourth portion and the second semiconductor layer.

12. The device according to claim 1, further comprising:
a seventh semiconductor layer provided between the fifth semiconductor layer and the first insulating film,
the seventh semiconductor layer including a first-conductivity-type impurity with a higher concentration than a concentration of a first-conductivity-type impurity in the first semiconductor layer.

13. A semiconductor device, comprising:
a first semiconductor layer of a first conductivity type;
a control electrode provided on the first semiconductor layer;
a first insulating film provided between the first semiconductor layer and the control electrode;
a second semiconductor layer of a second conductivity type provided on the first semiconductor layer, the second semiconductor layer including a portion facing the control electrode via the first insulating film;
a third semiconductor layer of the first conductivity type provided on the second semiconductor layer, the third semiconductor layer and the portion of the second semiconductor layer being arranged in a direction along an interface between the first semiconductor layer and the control electrode;
a fourth semiconductor layer of the second conductivity type provided on the first semiconductor layer at a position apart from the second semiconductor layer;
a fifth semiconductor layer of the second conductivity type and provided in the second semiconductor layer between the first semiconductor layer and the third semiconductor layer, the fifth semiconductor layer including a second-conductivity-type impurity with a higher concentration than a concentration of a second-conductivity-type impurity of the second semiconductor layer; and
a sixth semiconductor layer of the second conductivity type provided on the second semiconductor layer, the third semiconductor layer and sixth semiconductor layer being on the second semiconductor layer, the sixth semiconductor layer being electrically connected to the fifth semiconductor layer.
